(19) United States
(12) Patent Application Publication
(10) Pub. No.: US 2021/0378129 A1
(43) Pub. Date: Dec. 2, 2021

(54) SERVER STRUCTURE

(71) Applicant: Super Micro Computer Inc., San Jose, CA (US)

(72) Inventor: Ken-Sheng LIN, San Jose, CA (US)

(21) Appl. No.: 16/883,868

(22) Filed: May 26, 2020

(51) Int. Cl. H05K 7/14; H05K 5/02

(52) U.S. Cl. CPC H05K 7/1491; H05K 7/1487; H05K 5/0247; H05K 7/1427; H05K 7/1411

(57) ABSTRACT

A server structure includes an outer frame, a drawer box, a wire harness, and at least one wire harness bracket. The outer frame has a bottom plate and a fixed wall and forms an opening opposite to the fixed wall. The drawer box is passed into the outer frame through the opening. The wire harness has folded portions and is folded at each folded portion and disposed between the fixed wall and drawer box. The wire harness contains a signal cable and a power cable. The wire harness bracket ties the wire harness and has a sliding mat pressing at the bottom plate. When being removed from the opening, the drawer box moves away from the fixed wall and drives the wire harness to spread out each folded portion. The sliding mat supports the wire harness to separate the wire harness and bottom plate to facilitate movements and stretches.

### BACKGROUND OF THE INVENTION

### 1. Technical Field

The technical field of this disclosure relates to a server cabinet, and more particularly to a drawer type server structure.

### 2. Description of Related Art

In general, the structure of a conventional drawer type server cabinet includes a cabinet and a drawer accommodated into the cabinet, and at least a part of components of the server is carried in the drawer, so that the drawer can be pulled out to expose the components for easy maintenance, and a flat cable is generally provided between the drawer and the cabinet for their connection, and the length of the flat cable is long enough to allow the flat cable to extend from the inner rear wall of the cabinet to the entrance of the drawer.

When the drawer is retracted, the flat cable is bent and curled arbitrarily and squeezed easily, so that the flat cable is generally fixed to a swing arm coupled between the drawer and the cabinet, and the flat cable will be bent with the swing arm to avoid being squeezed. However, the different sized drawer and cabinet require a different sized swing arm, and thus incurring a higher cost and a more complicated installation.

In view of the aforementioned drawbacks of the prior art, the discloser of this disclosure based on years of experience in the related industry to conduct extensive research and experiment, and finally provided a feasible solution to overcome the drawbacks of the prior art.

### SUMMARY OF THE INVENTION

Therefore, it is a primary object of this disclosure to provide a drawer type server structure to overcome the aforementioned drawbacks of the prior art.

To achieve the aforementioned and other objectives, this disclosure discloses a server structure comprising an outer frame, a drawer box, a wire harness and at least one wire harness bracket. The outer frame has a bottom plate and a fixed wall therein and forms an opening configured to be opposite to the fixed wall

The drawer box is movably passed through the opening and installed into the outer frame. The wire harness has a plurality of folded portions, and the wire harness is folded at each folded portion and clamped between the fixed wall and the drawer box, and the wire harness contains a signal cable and a power cable configured into a bundle

The wire harness bracket is provided for tying the wire harness, and the wire harness bracket had a sliding mat pressing at the bottom plate

When the drawer box is removed from the opening, the drawer box moves away from the fixed wall to drive the wire harness to spread open each folded portion, and the sliding mat supports the wire harness, so as to separate the wire harness and the bottom plate.

In the server structure of this disclosure, the wire harness bracket forms a signal cable slot for tying the signal cable and a power cable slot for tying the power cable, and the signal cable slot and the power cable slot have different depths corresponding to the thickness of the signal cable and the power cable respectively. The signal cable slot and the power cable slot are configured to be side by side and communicated to each other.

The server structure of this disclosure further comprises a pair of end frames, one for tying an end of the wire harness and hanging on the fixed wall, and the other one for tying the other end of the wire harness and coupling the drawer box, and each of the end frames has a signal slot and a power cable slot therein for tying the signal cable and the power cable respectively, and the signal cable slot and the power cable slot have different depths corresponding to the thicknesses of the signal cable and the power cable respectively. Each end frame has a hook for hooking the fixed wall and the drawer box. Each end frame has a base plate with an edge which is bent to form the hook. Wherein, the fixed wall and the drawer box have a hanging plate separately, and the top edge of each base plate is bent to form the hook, and each hook is provided for hooking the top edge of each respective hanging plate, or the bottom edge of each base plate is bent to form the hook, and each hook penetrates and hooks into each respective hanging plate.

The server structure of this disclosure further comprises a plurality of cable ties for tying the signal cable and the power cable respectively.

In the server structure of this disclosure, the sliding mat has a curved surface abutting against the bottom plate.

When the drawer box is moved into opening or removed from the opening, the sliding mat supports the wire harness to separate the wire harness and the bottom plate. Such arrangement can prevent a too-large friction from interfering with the folding or stretching movement of the wire harness as well as unexpected twist or bend to assure the movement of each folded portion of the wire harness for the folding or stretching. In addition, the structure of the end frame makes the installation and removal of the wire harness easier.

### BRIEF DESCRIPTION OF THE DRAWINGS

FIG. 1 is a perspective view of a server structure in accordance with a preferred embodiment of this disclosure;

FIGS. 2 and 3 are schematic views of a wire harness in a server structure in accordance with a preferred embodiment of this disclosure;

FIG. 4 is an exploded view of a wire harness and an end frame in a server structure in accordance with a preferred embodiment of this disclosure;

FIG. 5 is a cross-sectional view of a wire harness and an end frame in a server structure in accordance with a preferred embodiment of this disclosure;

FIG. 6 is an exploded view of a wire harness and a wire harness bracket in a server structure in accordance with a preferred embodiment of this disclosure;

FIG. 7 is a cross-sectional view of a wire harness and a wire harness bracket in a server structure in accordance with a preferred embodiment of this disclosure; and

FIGS. 8 and 9 are schematic view showing an application status of a server structure in accordance with a preferred embodiment of this disclosure.

### DESCRIPTION OF THE PREFERRED EMBODIMENTS

The technical contents of this disclosure will become apparent with the detailed description of preferred embodiments accompanied with the illustration of related drawings as follows. It is intended that the embodiments and drawings disclosed herein are to be considered illustrative rather than restrictive.

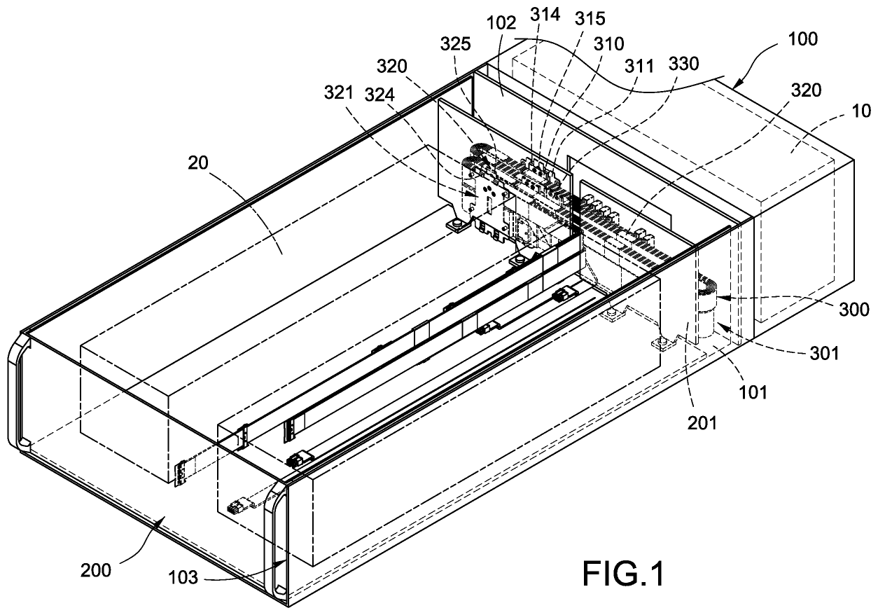

With reference to FIG. 1 for a server structure in accordance with a preferred embodiment of this disclosure, the server structure comprises an outer frame 100, a drawer box 200, a wire harness 300 and at least one wire harness bracket 330. In a preferred embodiment, the server structure of this disclosure further comprises a pair of end frames 310/320.

In this embodiment, the outer frame 100 includes but not limited to a flat rectangular body. The outer frame 100 comprises a bottom plate 101 and a fixed wall 102 therein. In this embodiment, the bottom plate 101 is horizontally installed to the fixed wall 102. The outer frame 100 forms an opening 103 disposed on a side of the bottom plate 101 and configured to be opposite to the fixed wall 102.

In this embodiment, the drawer box 200 is a flat rectangular body having a shape corresponsive to the outer frame 100, and the drawer box 200 is movably passed through the opening 103 and installed into the outer frame 100. The drawer box 200 has a movable wall 201, so that when the drawer box 200 is placed into the outer frame 100, the movable wall 201 and the fixed wall 102 are configured to be parallel and corresponsive to each other.

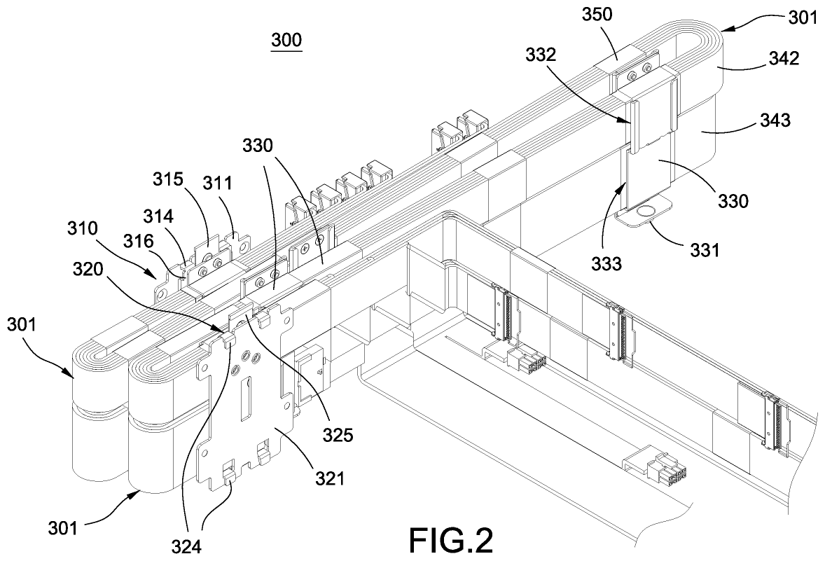

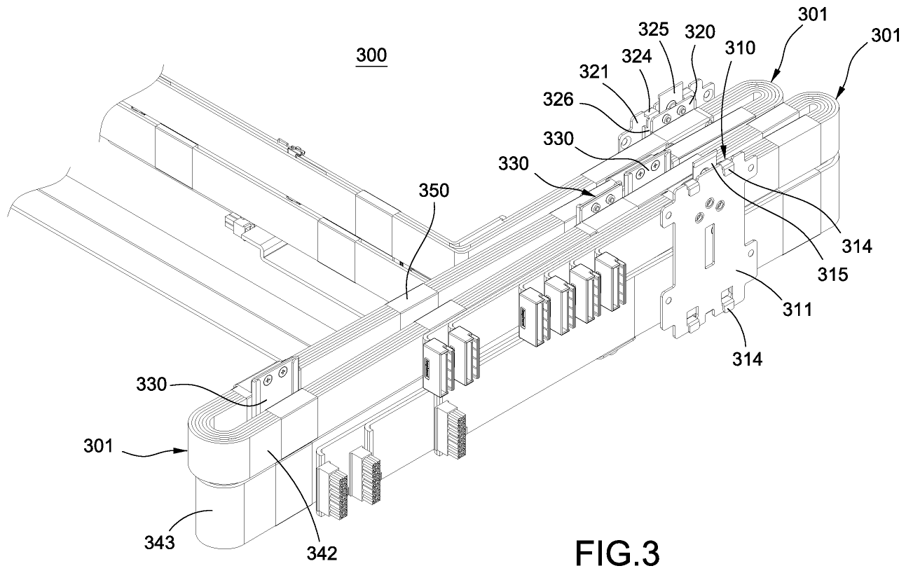

In FIGS. 1 to 3, the wire harness 300 is accommodated in the outer frame 100 and coupled between the outer frame 100 and the drawer box 200. In general, the wire harness 300 has an end electrically coupled to a movable equipment 20 in the drawer box 200 and the other end electrically coupled to a fixed equipment 10 in the outer frame 100, but the wire harness 300 may also be passed out from the outer frame 100 and coupled to an external equipment. In this embodiment, the wire harness 300 includes a signal cable 342 and a power cable 343 configured into a bundle, and the signal cable 342 and the power cable 343 have different thicknesses. The wire harness 300 is tied to a desired position by a cable tie 350, and the signal cable 342 and the power cable 343 are tied by the same cable tie 350. In a preferred embodiment, the signal cable 342 and the power cable 343 are tied by different cable ties 350 to facilitate installing the signal cable 342 and the power cable 343 to the end frame 310/320 and the wire harness bracket 330 respectively. Such arrangement can prevent the cables from being scattered or falling off during the process of installing the signal cable 342 and the power cable 343. Specifically, both ends of the wire harness 300 are coupled to the fixed wall 102 and the movable wall 201 respectively, and the wire harness 300 has a plurality of folded portions 301. When the drawer box 200 is placed into the outer frame 100, the wire harness 300 is folded at each folded portion 301 and clamped between the fixed wall 102 and the movable wall 201 of the drawer box 200.

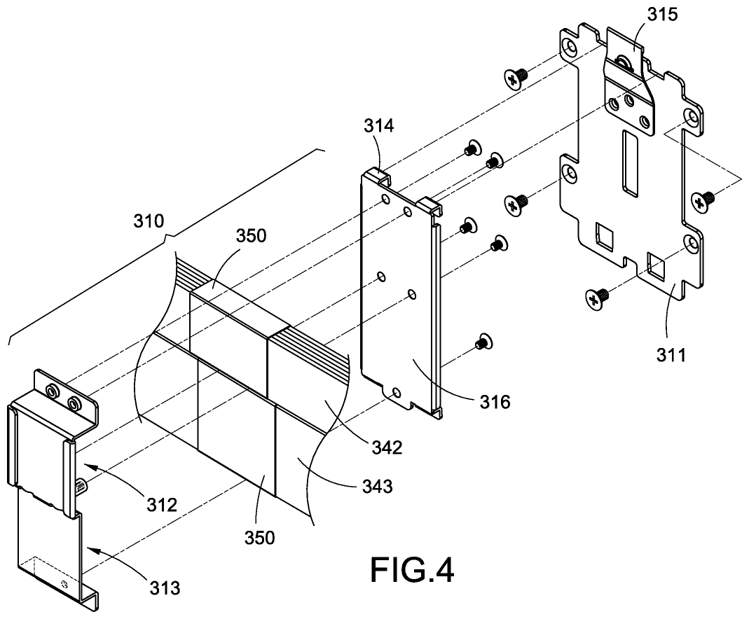

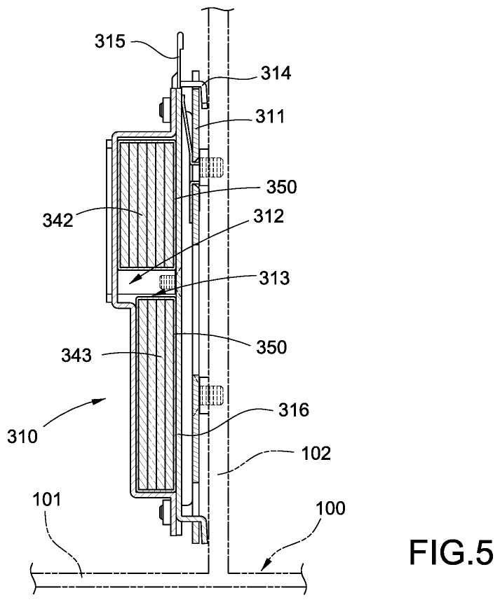

In FIGS. 1 to 5, the pair of end frames 310/320 are provided for tying both ends of the wire harness 300 and both ends of the wire harness 300 are fixed to the fixed wall 102 and the movable wall 201 respectively. In this embodiment, the structures of both end frames 310/320 are substantially the same, so that one of the end frames 310 is used as an example for illustration. In a preferred embodiment, the end frame 310 is a rectangular frame having a signal cable slot 312 formed therein for tying the signal cable 342 and a power cable slot 313 formed therein for tying the power cable 343. The signal cable slot 312 and the power cable slot 313 have different depths corresponsive to the thicknesses of the signal cable 342 and the power cable 343 respectively. The signal cable slot 312 and the power cable slot 313 are configured to be side by side and communicated with each other.

One of the end frames 310/320 ties an end of the wire harness 300 and hangs on the fixed wall 102, and the other end frame 310/320 ties the other end of the wire harness 300 and couples the drawer box 200. Each end frame 310/320 has at least one hook 314/324 for hooking the fixed wall 102 and the drawer box 200. Specifically, each end frame 310/320 is a circular frame and a part of each end frame 310/320 is a base plate 316/326. In a preferred embodiment, the hook 314/324 is formed by reversely folding the top edge or the bottom edge of the base plate 316/326. However, this disclosure is not limited to such arrangement. In this embodiment, both of the fixed wall 102 and the movable wall 201 of the drawer box 200 have a hanging plate 311/321, and the top edge of each hanging plate 311/321 is provided for hooking each respective end frame 310/320. Specifically, each base plate 316/326 is hooked to the top edge of each respective hanging plate 311/321 by the hook 314/324 at the top, and each base plate 316/326 is hooked to each respective hanging plate 311/321 by the hook 314/324 at the bottom, so as to make the hanging of the base plate 316/326 onto each hanging plate 311/321 easier. However, this disclosure is not limited to such arrangement only. For example, each end frame 310/320 may also be hooked to the top edge of the fixed wall 102 and the movable wall 20 by the hook 314/324 as well. Each hanging plate 311/321 has an elastic positioning arm 315/325 protruding therefrom, and when each end frame 310/320 hooks each respective hanging plate 311/321 by the hook 314/324, the elastic positioning arm 315/325 of each hanging plate 311/321 presses at the connected end frame 310/320 for its positioning. During the installation of the end frame 310/320, an operator presses down the elastic positioning arm 315/325 first (by using the end frame 310/320 to press down the elastic positioning arm 315/325), so that the hook 314/324 can be hooked and coupled to the top edge of the hanging plate 311/321. After the hook 314/324 is hooked and coupled to the top edge of the hanging plate 311/321, the operator releases the elastic positioning arm 315/325, so that the elastic positioning arm 315/325 bounces back to press and position the end frame 310/320. The operator can push away the elastic positioning arm 315/325 from pressing the end frame 310/320 to release the end frame 310/320 and facilitate the removal of the end frame 310/320.

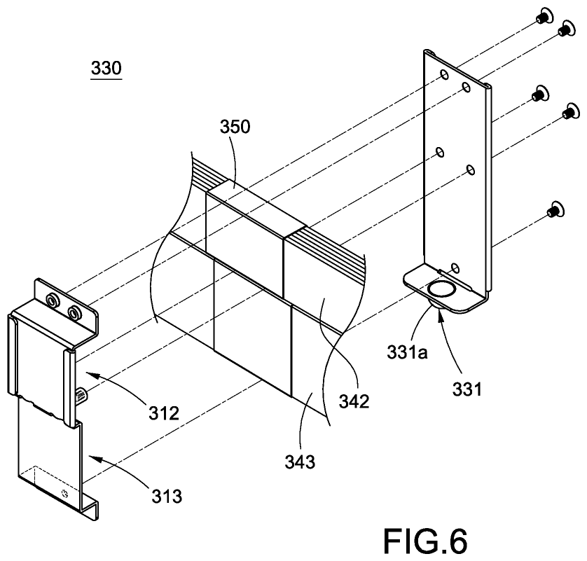

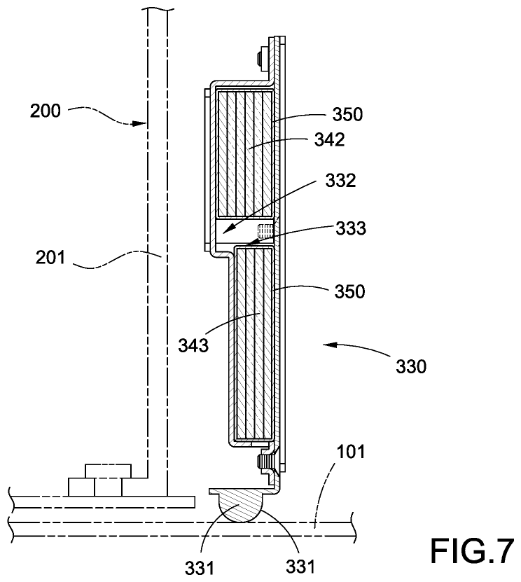

In FIGS. 1 to 3, 6 and 7, the wire harness bracket 330 ties the middle section of the wire harness 300, and the wire harness bracket 330 has a sliding mat 331 pressing at the bottom plate 101, and the sliding mat 331 has a curved surface 311a pressing at the bottom plate 101. The curved surface 311a presses at the bottom plate 101, so that there is a point contact between the sliding mat 331 and the bottom plate 101 and the friction between the two is minimized. The wire harness bracket 330 forms a signal cable slot 332 for tying the signal cable 342 and a power cable slot 333 for tying the power cable 343. The signal cable slot 332 and the power cable slot 333 have different depths corresponsive to the thicknesses of the signal cable 342 and the power cable 343 respectively. The signal cable slot 332 and the power cable slot 333 are configured to be side by side and communicated with each other.

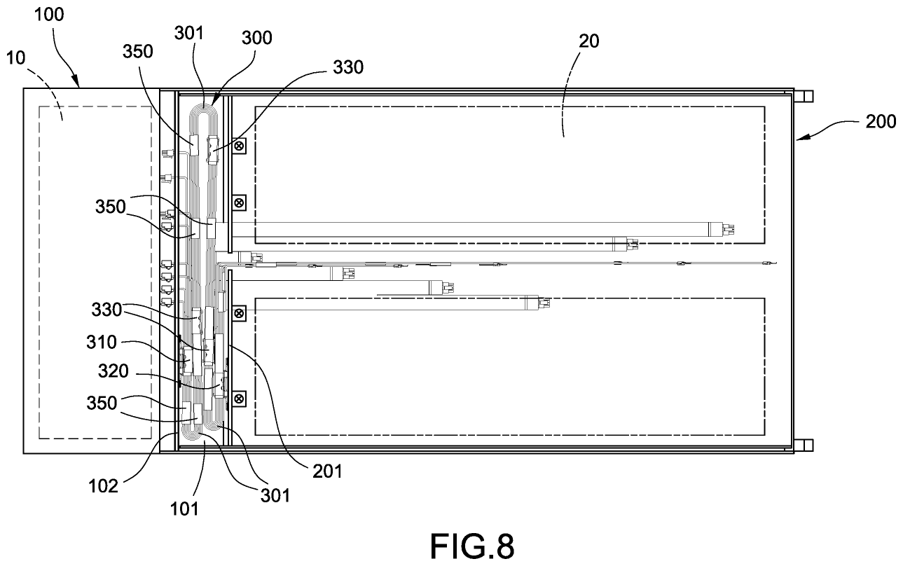

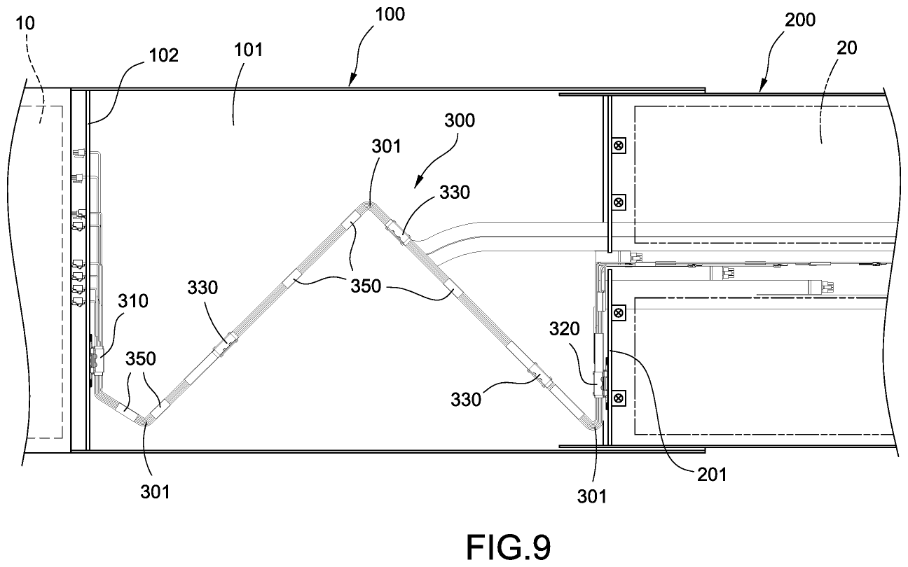

In FIGS. 8 and 9, when the drawer box 200 is moved into (as shown in FIG. 8) or removed from (as shown in FIG. 9) the opening 103, the drawer box 200 is moved respect to the fixed wall 102 to drive the wire harness 300 and spread open each folded portion 301, and the sliding mat 331 supports the wire harness 300, so that the wire harness 300 and the bottom plate 101 are separated. With the aforementioned structure, the friction between the wire harness 300 and the bottom plate 101 is only produced at the each sliding mat 331, so that the folding and stretching movement of the wire harness 300 will not be interfered by the friction. A smooth folding or stretching movement of the wire harness 300 prevents any unexpected twist and bend and assures folding and stretching movement of the wire harness 300 by each folded portion 301. In addition, the aforementioned structure incurs a manufacturing cost much lower than that of a traditional swing arm.

While this disclosure has been described by means of specific embodiments, numerous modifications and variations could be made thereto by those skilled in the art without departing from the scope and spirit of this disclosure set forth in the claims.

What is claimed is:

1. A server structure, comprising:
an outer frame, having a bottom plate and a fixed wall therein, and forming an opening configured to be opposite to the fixed wall;
a drawer box, movably passed through the opening and installed into the outer frame;
a wire harness, having a plurality of folded portions, and being folded at each folded portion and clamped between the fixed wall and the drawer box, and the wire harness containing a signal cable and a power cable configured into a bundle; and
at least one wire harness bracket, for tying the wire harness, and the wire harness bracket having a sliding mat pressing at the bottom plate,
wherein, when the drawer box is removed from the opening, the drawer box moves away from the fixed wall to drive the wire harness to spread open each folded portion, and the sliding mat supports the wire harness, so as to separate the wire harness and the bottom plate.

2. The server structure as claimed in claim 1, wherein the wire harness bracket forms a signal cable slot for tying the signal cable and a power cable slot for tying the power cable, and the signal cable slot and the power cable slot have different depths corresponding to the thickness of the signal cable and the power cable respectively.

3. The server structure as claimed in claim 2, wherein the signal cable slot and the power cable slot are configured to be side by side and communicated to each other.

4. The server structure as claimed in claim 1, further comprising a pair of end frames, one for tying an end of the wire harness and hanging on the fixed wall, and the other one for tying the other end of the wire harness and coupling the drawer box, and each of the end frames having a signal slot and a power cable slot therein for tying the signal cable and the power cable respectively, and the signal cable slot and the power cable slot having different depths corresponding to the thicknesses of the signal cable and the power cable respectively.

5. The server structure as claimed in claim 4, wherein each end frame has a hook for hooking the fixed wall and the drawer box.

6. The server structure as claimed in claim 5, wherein each end frame has a base plate with an edge which is bent to form the hook.

7. The server structure as claimed in claim 5, wherein the fixed wall and the drawer box have a hanging plate separately, and the top edge of each base plate is bent to form the hook, and each hook is provided for hooking the top edge of each respective hanging plate.

8. The server structure as claimed in claim 5, wherein the fixed wall and the drawer box have a hanging plate separately, and the bottom edge of each base plate is bent to form the hook, and each hook penetrates and hooks into each respective hanging plate.

9. The server structure as claimed in claim 1, further comprising a plurality of cable ties for tying the signal cable and the power cable respectively.

10. The server structure as claimed in claim 1, wherein the sliding mat has a curved surface abutting against the bottom plate.
